(19) United States
(12) Patent Application Publication
(10) Pub. No.: US 2022/0239849 A1
(43) Pub. Date: Jul. 28, 2022

(54) IMAGING DEVICE AND ELECTRONIC APPARATUS

(71) Applicant: SONY SEMICONDUCTOR SOLUTIONS CORPORATION, KANAGAWA (JP)

(72) Inventors: HIDEKI ARAI, KANAGAWA (JP); YUSUKE OTAKE, KANAGAWA (JP); TAKURO MURASE, KANAGAWA (JP)

(21) Appl. No.: 17/612,533

(22) PCT Filed: Apr. 28, 2020
(86) PCT No.: PCT/JP2020/018154

§ 371 Date: Nov. 18, 2021

(30) Foreign Application Priority Data
May 29, 2019 (JP) 2019-100342

(51) Int. Cl. H04N 5/33; H01L 27/146

(52) U.S. Cl. CPC H04N 5/33; H01L 27/1464; H01L 27/1463; H01L 27/14649

(57) ABSTRACT

Provided is an imaging device that makes it possible to exhibit a better imaging performance. The imaging device includes a semiconductor layer, a pixel separation section, a plurality of photoelectric conversion sections, and a plurality of electric charge voltage conversion sections. The semiconductor layer has a surface that extends in an in-plane direction, and a back face positioned on an opposite side of the surface in a thickness direction. The pixel separation section extends from the surface to the back face in the thickness direction, and separates the semiconductor layer into a plurality of pixel regions in the in-plane direction. The plurality of photoelectric conversion sections is respectively provided in the plurality of pixel regions of the semiconductor layer separated by the pixel separation section, and is each configured to generate, by a photoelectric conversion, electric charge corresponding to a light amount of incident light from the back face. The plurality of electric charge voltage conversion sections is respectively provided in a plurality of gap regions, in which the plurality of gap regions is disposed in the in-plane direction between the plurality of photoelectric conversion sections and the pixel separation section out of the plurality of pixel regions, and the plurality of electric charge voltage conversion sections respectively accumulates the electric charges generated by the respective plurality of photoelectric conversion sections, and respectively converts the accumulated electric charges into electric signals and outputs the converted electric signals.

### TECHNICAL FIELD

The present disclosure relates to an imaging device that performs imaging by performing a photoelectric conversion, and to an electronic apparatus provided with the imaging device.

### BACKGROUND ART

To date, the Applicant has proposed an imaging device in which electric charge converted from incident light by a photoelectric conversion section is read out after temporarily holding the electric charge in an electric charge accumulation section (for example, see Patent Literature 1).

### CITATION LIST

### Patent Literature

Patent Literature 1: Japanese Unexamined Patent Application Publication No. 2017-168566

### SUMMARY OF THE INVENTION

Incidentally, what is demanded for such an imaging device is to suppress an entry of unnecessary light between adjacent pixel regions.

Accordingly, it is desirable to provide an imaging device that makes it possible to exhibit more superior imaging performance and an electronic apparatus provided with the imaging device.

An imaging device according to one embodiment of the present disclosure includes a semiconductor layer, a pixel separation section, a plurality of photoelectric conversion sections, and a plurality of electric charge voltage conversion sections. The semiconductor layer has a surface that extends in an in-plane direction, and a back face positioned on an opposite side of the surface in a thickness direction that is orthogonal to the in-plane direction. The pixel separation section extends from the surface to the back face in the thickness direction, and separates the semiconductor layer into a plurality of pixel regions in the in-plane direction. The plurality of photoelectric conversion sections is respectively provided in the plurality of pixel regions of the semiconductor layer separated by the pixel separation section, and is each configured to generate, by a photoelectric conversion, electric charge corresponding to a light amount of incident light from the back face. The plurality of electric charge voltage conversion sections is respectively provided in a plurality of gap regions, in which the plurality of gap regions is disposed in the in-plane direction between the plurality of photoelectric conversion sections and the pixel separation section out of the plurality of pixel regions, and the plurality of electric charge voltage conversion sections respectively accumulates the electric charges generated by the respective plurality of photoelectric conversion sections, and respectively converts the accumulated electric charges into electric signals and outputs the converted electric signals.

An electronic apparatus according to one embodiment of the present disclosure is provided with the imaging device described above.

### BRIEF DESCRIPTION OF THE DRAWINGS

FIG. 1 is a block diagram illustrating a configuration example of an imaging device according to an embodiment of the present disclosure.

FIG. 2 is a circuit diagram illustrating a circuit configuration of a sensor pixel in the imaging device illustrated in FIG. 1.

FIG. 3 is a plan diagram schematically illustrating a plan configuration of a portion of the sensor pixel in the imaging device illustrated in FIG. 1.

FIG. 4 is a cross-sectional diagram schematically illustrating a cross-sectional configuration of the sensor pixel illustrated in FIG. 3.

FIG. 5 is a diagram illustrating an example of an image signal generation process according to an embodiment.

FIG. 6 is a plan diagram schematically illustrating a plan configuration of a sensor pixel as a first modification example according to an embodiment.

FIG. 7A is a plan diagram illustrating a wiring line pattern in a first layer of the sensor pixel illustrated in FIG. 6.

FIG. 7B is a plan diagram illustrating a wiring line pattern in a second layer of the sensor pixel illustrated in FIG. 6.

FIG. 7C is a plan diagram illustrating a wiring line pattern in a third layer of the sensor pixel illustrated in FIG. 6.

FIG. 7D is a plan diagram illustrating a wiring line pattern in a fourth layer of the sensor pixel illustrated in FIG. 6.

FIG. 8 is a plan diagram schematically illustrating a plan configuration of a sensor pixel as a second modification example according to an embodiment.

FIG. 9 is a cross-sectional diagram schematically illustrating a cross-sectional configuration of a sensor pixel as a third modification example according to an embodiment.

FIG. 10 is a cross-sectional diagram schematically illustrating a cross-sectional configuration of a sensor pixel as a fourth modification example according to an embodiment.

FIG. 11A is a plan diagram schematically illustrating a plan configuration of a sensor pixel as a fifth modification example according to an embodiment.

FIG. 11B is a cross-sectional diagram schematically illustrating a cross-sectional configuration of the sensor pixel illustrated in FIG. 11A.

FIG. 12 is a schematic diagram illustrating an example of entire configuration of an electronic apparatus.

FIG. 13 is a block diagram depicting an example of schematic configuration of a vehicle control system.

FIG. 14 is a diagram of assistance in explaining an example of installation positions of an outside-vehicle information detecting section and an imaging section.

FIG. 15 is a block diagram illustrating a first modification example of the imaging device according to the present disclosure.

FIG. 16 is a block diagram illustrating a second modification example of the imaging device according to the present disclosure.

### MODES FOR CARRYING OUT THE INVENTION

In the following, some embodiments of the present disclosure are described in detail with reference to the drawings. The description will be made in the following order.
1. Embodiment

An example of a solid-state imaging device in which an electric charge voltage conversion section is disposed at a peripheral part of each pixel region separated by a light-blocking wall that penetrates a semiconductor layer in a thickness direction.
2. First Modification Example

An example in which a layout of each component in a gap region of each pixel region is changed.
3. Second Modification Example

Another example in which a layout of each component in a gap region of each pixel region is changed.
4. Third Modification Example

An example in which a scattering structure that scatters incident light is provided in the vicinity of a surface of the semiconductor layer.
5. Fourth Modification Example

An example in which a trench gate that joins a photoelectric conversion section and a transfer transistor is further provided.
6. Fifth Modification Example

An example in which a horizontal light-blocking film is further provided between the photoelectric conversion section and the electric charge voltage conversion section.
7. Example of Application to Electronic Apparatus
8. Example of Application to Mobile Body
9. Other Modification Examples

<1. Embodiment>

[Configuration of Solid-State Imaging Device 101]

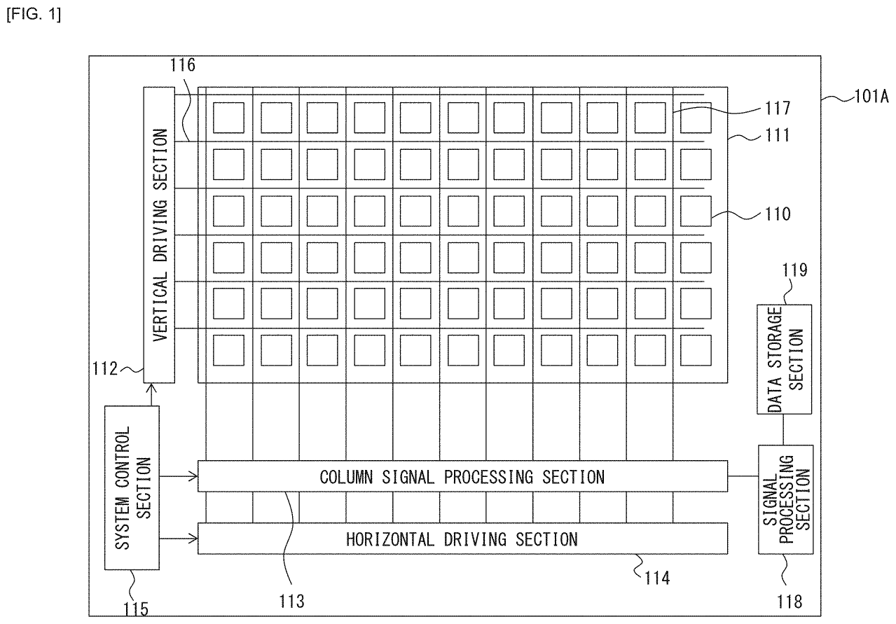

FIG. 1 is a block diagram illustrating a configuration example of a function of a solid-state imaging device 101 according to an embodiment of the present technology.

The solid-state imaging device 101 is a so-called backside illumination image sensor of a global shutter type, such as a CMOS (Complementary Metal Oxide Semiconductor) image sensor. The solid-state imaging device 101 receives light from a subject, photoelectrically converts the light, and generates an image signal, thereby performing imaging of an image.

The global shutter type is basically a type of performing a global exposure, in which an exposure of entire pixels is started together and the exposure of the entire pixels is ended together. Here, the entire pixels mean all of the pixels of a portion appearing in an image, and dummy pixels and the like are excluded. In addition, the global shutter type also includes a type of moving a region where the global exposure is to be performed while the global exposure is performed in units of a plurality of rows (e.g., several tens of rows) instead of performing the global exposure on the entire pixels together, as long as a time difference or a distortion of an image is small enough not to cause a problem. Also included in the global shutter type is a type of performing the global exposure on pixels in a predetermined region instead of performing the global exposure on all of the pixels of the portion appearing in the image.

The backside illumination image sensor refers to an image sensor having a configuration in which a photoelectric conversion section such as a photodiode that receives light from a subject and converts the light into an electric signal is provided between a light-receiving surface on which the light from the subject is incident and a wiring line layer provided with wiring lines such as transistors that drive respective pixels.

The solid-state imaging device 101 includes, for example, a pixel array section 111, a vertical driving section 112, a column signal processing section 113, a data storage section 119, a horizontal driving section 114, a system control section 115, and a signal processing section 118.

In the solid-state imaging device 101, the pixel array section 111 is formed on a semiconductor substrate 11 (described later). Peripheral circuits such as the vertical driving section 112, the column signal processing section 113, the data storage section 119, the horizontal driving section 114, the system control section 115, and the signal processing section 118 are formed on the same semiconductor substrate 11 as the pixel array section 111, for example.

The pixel array section 111 has a plurality of sensor pixels 110 including a photoelectric conversion section (described later) that generates and accumulates electric charge corresponding to an amount of light entered from the subject. The sensor pixels 110 are arranged in each of a lateral direction (a row direction) and a vertical direction (a column direction) as illustrated in FIG. 1A. In the pixel array section 111, a pixel driving line 116 is wired along the row direction for each pixel row configured by the sensor pixels 110 arranged in a row in the row direction, and a vertical signal line (VSL) 117 is wired along the column direction for each pixel column configured by the sensor pixels 110 arranged in a row in the column direction.

The vertical driving section 112 is configured by a shift register or an address decoder. The vertical driving section 112 supplies a signal and the like to each of the plurality of sensor pixels 110 via the plurality of pixel driving lines 116, thereby driving all of the plurality of sensor pixels 110 in the pixel array section 111 together, or driving the plurality of sensor pixels on a pixel row basis.

The vertical driving section 112 has, for example, two scanning systems of a read-out scanning system and a sweep scanning system. The read-out scanning system selectively scans unit pixels of the pixel array section 111 row by row in order to read out signals from the unit pixels. The sweep scanning system performs, on a read-out row on which a read-out scanning is to be performed by the read-out scanning system, a sweep scanning prior to the read-out scanning by the duration of a shutter speed.

The sweep scanning of the sweep scanning system sweeps unnecessary electric charge from the photoelectric conversion sections 51 of the unit pixels of the read-out row (described later). This is called a reset. Then, by the sweeping of the unnecessary electric charge by the sweep scanning system, i.e., the reset, a so-called electronic shutter operation is performed. Here, the electronic shutter operation refers to an operation of discarding photoelectric charge of the photoelectric conversion sections 51 and newly starting the exposure, that is, newly starting the accumulation of the photoelectric charge.

The signals read by the read-out operation by the read-out scanning system correspond to an amount of light that has entered during the immediately preceding read-out operation or on or after the electronic shutter operation. A period from a read-out timing by the immediately preceding read-out operation or a sweeping timing by the electronic shutter operation to a read-out timing by the current read-out operation is an accumulation time of the photoelectric charge in the unit pixels, that is, an exposure time.

The signals outputted from the respective unit pixels of the pixel row selected and scanned by the vertical driving section 112 are supplied to the column signal processing section 113 via each of the vertical signal lines 117. The column signal processing section 113 performs a predetermined signal process on the signals outputted via the VSLs 117 from the respective unit pixels of the selected rows, for each pixel column of the pixel array section 111, and temporarily holds pixel signals having been subjected to the signal process.

Specifically, the column signal processing section 113 is configured by, for example, a shift register or an address decoder, and performs a noise removal process, a correlated double-sampling process, an A/D (Analog/Digital) conversion A/D conversion process of the analog pixel signals, and the like to generate the digital pixel signals. The column signal processing section 113 supplies the generated pixel signals to the signal processing section 118.

The horizontal driving section 114 is configured by a shift register, an address decoder, or the like, and selects, in order, unit circuits corresponding to the pixel column of the column signal processing section 113. By the selective scanning by the horizontal driving section 114, the pixel signal having been subjected to the signal process for each unit circuit by the column signal processing section 113 is outputted in order to the signal processing section 118.

The system control section 115 is configured by, for example, a timing generator that generates various timing signals. The system control section 115 performs drive controls of the vertical driving section 112, the column signal processing section 113, and the horizontal driving section 114 on the basis of the timing signals generated by the timing generator.

The signal processing section 118 performs a signal process such as an arithmetic process on the pixel signals supplied from the column signal processing section 113 while temporarily holding data in the data storage section 119 on an as-necessary basis, and outputs an image signal configured by each of the pixel signals.

The data storage section 119 temporarily holds data necessary for the signal process upon the signal process by the signal processing section 118.

[Configuration of Sensor Pixel 110]

(Example of Circuit Configuration)

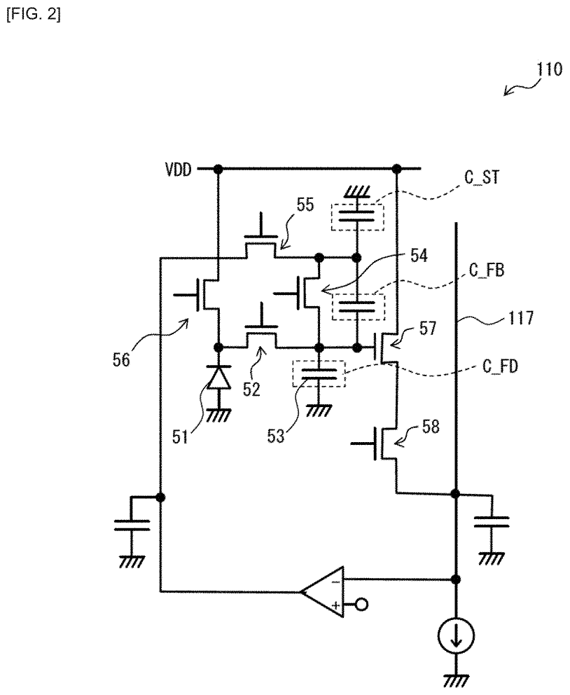

Next, referring to FIG. 2, an example of a circuit configuration of the sensor pixel 110 provided in the pixel array section 111 illustrated in FIG. 1A will be described. FIG. 2 illustrates an example of a circuit configuration of any one of the plurality of sensor pixels 110 provided in the pixel array section 111.

In an example illustrated in FIG. 2, the sensor pixel 110 achieves an FD-type global shutter. In the example of FIG. 2, the sensor pixel 110 in the pixel array section 111 includes, for example, the photoelectric conversion section (PD) 51, an electric charge transfer section (TG) 52, a floating diffusion (FD) 53 as an electric charge retaining section and an electric charge voltage conversion section, a reset transistor (RST) 54, a feedback enable transistor (FBEN) 55, a discharge transistor (OFG) 56, an amplification transistor (AMP) 57, a selection transistor (SEL) 58, and the like.

Further, in this example, the TG 52, the FD 53, the RST 54, the FBEN 55, the OFG 56, the AMP 57, and the SEL 58 are each an N-type MOS transistor. Drive signals are supplied to respective gate electrodes of the TG 52, the FD 53, the RST 54, the FBEN 55, the OFG 56, the AMP 57, and the SEL 58. The drive transistors are each a pulse signal in which a high level state is an active state, i.e., an ON state and a low level state is a non-active state, i.e., an OFF state. It should be noted that, hereinafter, placing the drive signal into the active state is also referred to as turning on the drive signal, and placing the drive signal into the non-active state is also referred to as turning off the drive signal.

The PD 51 is a photoelectric conversion element configured by, for example, a PN-junction photodiode. The PD 51 receives light from the subject, generates electric charge corresponding to an amount of received light by a photoelectric conversion, and accumulates the electric charge.

The TG 52 is coupled between the PD 51 and the FD 53, and transfers the electric charge accumulated in the PD 51 to the FD 53 in response to the drive signal applied to the gate electrode of the TG 52.

The FD 53 is a region that temporarily holds the electric charge accumulated in the FD 51, in order to achieve a global shutter function. The FD 53 is also a floating diffusion region that converts the electric charge transferred from the PD 51 via the TG 52 into an electric signal (e.g., a voltage signal) and outputs the electric signal. The RST 54 is coupled to the FD 53, and the VSL 117 is coupled to the FD 53 via the AMP 57 and the SEL 58.

The RST 54 has a drain coupled to the FBEN 55 and a source coupled to the FD 53. The RST 54 initializes, i.e., resets, the FD 53 in response to the drive signal applied to its gate electrode. It should be noted that, as illustrated in FIG. 2, the drain of the RST 54 forms a parasitic capacitance C__{ST} between the drain thereof and the ground, and forms a parasitic capacitance C__{FB} between the drain thereof and the gate electrode of the AMP 57.

The FBEN 55 controls a reset voltage to be applied to the RST 54.

The OFG 56 has a drain coupled to a power source VDD and a source coupled to the PD 51. A cathode of the PD 51 is commonly coupled to a source of the OFG 56 and a source of the TG 52. The OFG 56 initializes, i.e., resets, the PD 51 in response to the drive signal applied to its gate electrode. The reset of the PD 51 means depleting the PD 51.

The AMP 57 has the gate electrode coupled to the FD 53 and a drain coupled to the power source VDD, and serves as an input section of a source follower circuit that reads out the electric charge obtained by the photoelectric conversion at the PD 51. That is, a source of the AMP 57 is coupled to the VSL 117 via the SEL 58, whereby the AMP 57 configures the source follower circuit together with a constant current source coupled to one end of the VSL 117.

The SEL 58 is coupled between the source of the AMP 57 and the VSL 117, and a selection signal is supplied to the gate electrode of the SEL 58. The SEL 58 is placed into an electric conduction state when its selection signal is turned on, and the sensor pixel 110 in which the SEL 58 is provided is placed into a selected state. When the sensor pixel 110 is placed into the selected state, the pixel signal outputted from the AMP 57 is read out by the column signal processing section 113 via the VSL 117.

In addition, in the pixel array section 111, the plurality of pixel driving lines 116 is wired, for example, for each pixel row. Further, the respective drive signals are supplied from the vertical driving section 112 to the selected sensor pixels 110 via the plurality of pixel driving lines 116.

It should be noted that the pixel circuit illustrated in FIG. 2 is an example of the pixel circuit usable for the pixel array section 111, and it is possible to use a pixel circuit having another configuration.

(Plan Configuration Example and Cross-Sectional Configuration Example)

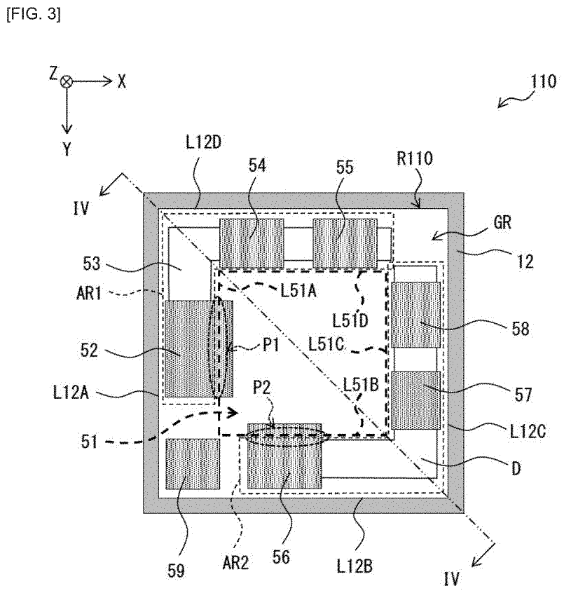

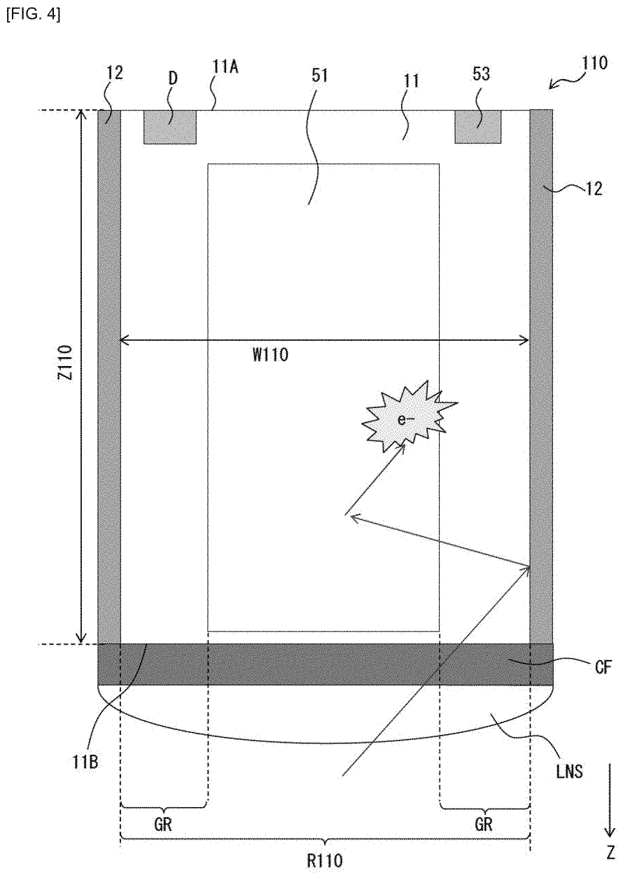

Next, referring to FIGS. 3 and 4, an example of a plan configuration and an example of a cross-sectional configuration of the sensor pixel 110 provided in the pixel array section 111 of FIG. 1A will be described. FIG. 3 illustrates an example of a plan configuration of one of the plurality of sensor pixels 110 structuring the pixel array section 111. FIG. 4 illustrates an example of a cross-sectional configuration of one sensor pixel 110, which corresponds to a cross-section taken along the IV-IV cutting line illustrated in FIG. 3 and as seen in an arrow direction.

As illustrated in FIGS. 3 and 4, the pixel array section 111 has PD 51 embedded in the semiconductor substrate 11 extending in, for example, an X-Y plane, and a pixel separation section 12 provided to surround the PD 51 in the semiconductor substrate 11. The semiconductor substrate 11 is formed by a semiconductor material such as Si (silicon), and has a surface 11A extending in the X-Y plane and a back face 11B positioned on an opposite side of the surface 11A in a Z-axis direction that is a thickness direction orthogonal to the X-Y plane. For example, a color filter CF and an on-chip lens LNS are stacked in this order on the back face 11B. The pixel separation section 12 is a physical separation wall that extends from the surface 11A to the back face 11B in the thickness direction and that separates the semiconductor substrate 11 into a plurality of pixel regions R110 in the X-Y plane.

It should be noted that, in the present embodiment, the semiconductor substrate 11 is, for example, of a P-type (a first conductivity type), and the PD 51 is of an N-type (a second conductivity type).

The sensor pixel 110 is formed one by one in one pixel region R110 partitioned by the pixel separation section 12. The adjacent sensor pixels 110 are electrically separated from each other, optically separated from each other, or optically and electrically separated from each other by the pixel separation section 12. The pixel separation section 12 may be formed by a single layer film or a multi-layer film of an insulator such as a silicon oxide (SiO₂), a tantalum oxide (Ta₂O₅), a hafnium oxide (HfO₂), or an aluminum oxide (Al₂O₃), for example. Further, the pixel separation section 12 may be formed by a stack of a single layer film or a multilayer film of an insulator such as a tantalum oxide, a hafnium oxide, or an aluminum oxide, and a silicon oxide film. It is possible for the pixel separation section 12 formed by the insulator described above to optically and electrically separate the sensor pixels 110. The pixel separation section 12 configured by such an insulator is also referred to as RDTI (Rear Deep Trench Isolation). In addition, the pixel separation section 12 may include a void therein. Even in such a case, it is possible for the pixel separation section 12 to optically and electrically separate the sensor pixels 110. Further, the pixel separation section 12 may be formed by a metal having a light-blocking property, such as tantalum (Ta), aluminum (Al), silver (Ag), gold (Au), or copper (Cu), for example. In this case, it is possible to optically separate the sensor pixels 110. Further, polysilicon (Polycrystalline Silicon) may be used as a constituent material of the pixel separation section 12.

As illustrated in FIG. 3, the pixel region R110 of each of the sensor pixels 110 includes, in addition to the photoelectric conversion section (PD) 51, a first active region AR1 and a second active region AR2 coupled to the PD 51. The pixel region R110 has a rectangular, preferably square, outer edge including L12A to L12D within the X-Y plane. The PD 51 has a substantially rectangular outer edge including straight parts L51A to L51D respectively opposed to the straight parts L12A to L12D in the X-Y plane. Both the first active region AR1 and the second active region AR2 are provided in a gap region GR between the PD 51 and the pixel separation section 12.

The first active region AR1 is provided with, for example, the TG 52, the FD 53, the RST 54, the FBEN 55, and the like. The TG 52 is provided in a portion of the gap region GR sandwiched between the straight part L51A and the straight part L12A. However, a portion of the TG 52 is coupled to the PD 51 at a first connection point P1. In addition, the RST 54 and the IBEN 55 are provided in a portion of the gap region GR sandwiched between the straight part L51D and the straight part L12D, for example. Further, the FD 53 is provided from a portion of the gap region GR sandwiched between the straight part L51A and the straight part L12A to a portion of the gap region GR sandwiched between the straight part L51D and the straight part L12D.

The second active region AR2 is provided with, for example, the OFG 56, the AMP 57, the SEL 58, and the like. It should be noted that a drain D is shared by the OFG 56 and the AMP 57. The OFG 56 is provided in a portion of the gap region GR sandwiched between the straight part L51B and the straight part L12B. However, a portion of the OFG 56 is coupled to the PD 51 at a second connection point P2. In addition, the AMP 57 and the SEL 58 are provided in a portion of the gap region GR sandwiched between the straight part L51C and the straight part L 12C. Further, the drain D is provided from a portion of the gap region GR sandwiched between the straight part L51B and the straight part L12B to a portion of the gap region GR sandwiched between the straight part L51C and the straight part L12C.

As illustrated in FIG. 4, the FD 53 is provided between the surface 11A and the PD 51 in the thickness direction (the Z-axis direction).

In addition, the solid-state imaging device 101 receives, for example, visible light from the subject to perform the imaging. However, the solid-state imaging device 101 is not limited thereto, and may receive, for example, infrared light to perform the imaging. In such a case, the sensor pixel 110 has a ratio of a thickness Z110 to a width W110 along the X-Y plane, i.e., an aspect ratio of, for example, three or greater. More specifically, for example, the thickness Z110 is 8.0 μm where the width W110 is 2.2 μm. The relatively high aspect ratio in this manner results in better optical and electrical separations between the sensor pixels 110, for example.

Further, in the sensor pixel 110, one or more well contacts 59 such as copper are coupled to the gap region GR of the pixel region R110 which is other than a region in which the PD 51 is formed. In the pixel array section 111, the semiconductor substrate 11 in each pixel region R110 is partitioned for each sensor pixel 110 by the pixel separation section 12 and is thus electrically isolated. For this reason, a potential of the semiconductor substrate 11 in each pixel region R110 is stabilized by the connection of the well contact 59.

[Image Signal Generation Process of Solid-State Imaging Device 101]

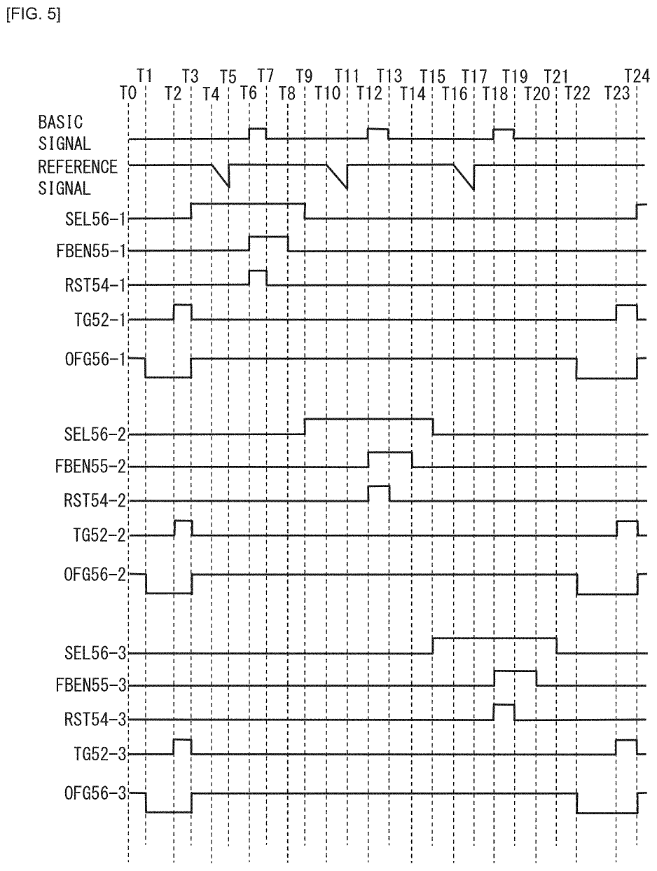

FIG. 5 is a time chart illustrating an example of an image signal generation process in the solid-state imaging device 101. FIG. 5 illustrates the image signal generation process of the sensor pixels 110 disposed from the first row to the third row in the pixel array section 111. In FIG. 5, a basic signal represents a basic signal to be supplied to the column signal processing section 113. In the basic signal, a broken line represents a potential at 0 V of the basic signal. S52 and S54 to S58 represent respective control signals to be inputted to the TG 52, the RST 54, the FBEN 55, the OFG 56, the AMP 57, and the SEL 58. These are distinguished by giving row number because the control signal different for each row is inputted. For example, S58-1 to S58-3 represent the respective control signals to be inputted to the gate electrodes of the SELs 58 of the sensor pixels 110 from the first row to the third row. Further, image signals in FIG. 5 represent waveforms of the image signals to be outputted from the sensor pixels 110. These image signals are also distinguished by giving the row number.

At a time T0, a second basic signal is supplied to the column signal processing section 113. The supply of the second basic signal continues to a time T6. Further, at the time T0, ON signals are inputted as the control signals S56-1 to S56-3, and the respective OFGs 56 become electrically conductive in the sensor pixels 110 from the first row to the third row to reset the PDs 51. Thereafter, the inputting of the ON signals to the respective OFGs 56 in the sensor pixels 110 from the first row to the third row is stopped at a time Ti. This starts the exposure. That is, the PDs 51 start holding the generated electric charge in the sensor pixels 110 from the first row to the third row.

From a time T2 to a time T3, the ON signals are inputted as the control signals S52 to the TGs 52 of all the sensor pixels 110 disposed in the pixel array section 111, and all the TGs 52 become electrically conductive. As a result, the electric charge held in the PDs 51 are transferred to the respective FDs 56.

At the time T3, the inputting of the ON signals to the TGs 52 of the sensor pixels 110 from the first row to the third row is stopped. At the same time, the ON signals are inputted to the respective OFGs 56 of the sensor pixels 110 from the first row to the third row. As a result, the exposure is stopped. It should be noted that the inputting of the ON signals to the respective OFGs 56 of the sensor pixels 110 from the first row to the third row is continued until a time T22. Further, at the time T3, the ON signal to the SELs 58 of the sensor pixels 110 in the first row is inputted, and the SELs 58 of the sensor pixels 110 in the first row is placed into an electric conduction state. It should be noted that the inputting of the ON signal to the SELs 58 of the sensor pixels 110 in the first row is continued until a time T9. Next, a reference signal is generated from a time T4 to a time T5, and an analog-to-digital conversion of the image signals is performed.

At the time T6, the ON signals are inputted as the control signal S55 and the control signal S54 to the respective FBEN 55 and RST 54 in the sensor pixels 110 in the first row, and the FBEN 55 and the RST 54 are placed into an electric conduction state. At the same time, the ON signal is supplied to the column signal processing section 113 as a first basic signal. The supply of the first basic signal is continued until a time T7. As a result, the reset is performed on the sensor pixels 110 disposed in the first row.

Next, at the time T7, the inputting of the ON signal to the RST 54 is stopped. At the same time, a supply of a second basic signal is started for the column signal processing section 113. It should be noted that the supply of the second basic signal is continued until a time T12. Thereafter, the inputting of the ON signal to the FBEN 55 is stopped at a time T8. The foregoing completes the processes of the analog-to-digital conversion of the image signals and the reset in the sensor pixels 110 disposed in the first row.

Next, at the time T9, the inputting of the ON signals to the SELs 58 of the sensor pixels 110 in the first row is stopped, and the ON signals are inputted to the SELs 58 of the sensor pixels 110 in the second row. Thereafter, until a time T15, processes similar those from the time T3 to the time T9 are performed for the sensor pixels 110 disposed in the second row.

Next, at the time T15, the inputting of the ON signals to the SELs 58 of the sensor pixels 110 in the second row is stopped, and the ON signals are inputted to the SELs 58 of the sensor pixels 110 in the third row. Thereafter, until a time T21, processes similar those from the time T9 to the time T15 are performed for the sensor pixels 110 disposed in the third row.

From the time T21 to a time T23, processes similar to those from the time T3 to the time t9 are performed for the sensor pixels 110 disposed in all the rows, and the image signals corresponding to one screen are acquired from the pixel array section 111 and the reset of all the sensor pixels 110 disposed in the pixel array section 111 is completed. In addition, the inputting of the ON signals to the respective OFGs 56 of the sensor pixel 110 from the first row to the third row is stopped, and the exposure is newly started (a time T22).

From the time T23 to a time T24, processes similar to those from the time T2 to the time T3 are performed, and the exposure is stopped and the electric charge is transferred from the PDs 51.

It should be noted that the inputting of the ON signals to the respective OFGs 56 of the sensor pixels 110 and the stoppage of the inputting thereof are performed together for the sensor pixels 110 disposed in all the rows of the pixel array section 111. Similarly, the inputting of the ON signals to the respective TGs 52 of the sensor pixels 110 and the stoppage of the inputting are performed together for the sensor pixels 110 disposed in all the rows of the pixel array section 111. As a result, it is possible to start and end the exposure for all the sensor pixels 110 disposed in the pixel array section 111 together.

As described above, the starting and the ending of the exposure are performed for all the sensor pixels 110 disposed in the pixel array section 111 together. Thus, it is possible to obtain an image signal having a less distortion as compared with a rolling shutter system.

[Effects of Solid-State Imaging Device 101]

As described above, in the solid-state imaging device 101 according to the present embodiment, the semiconductor substrate 11 is separated into the plurality of pixel regions R110 in an X-Y plane direction by providing the pixel separation section 12 that extends from the surface 11A to the back face 11B of the semiconductor substrate 11. Thus, a color mixture reduction effect between the adjacent sensor pixels 110 is obtained.

Further, the FD 53 is provided in the gap region GR. Thus, a false signal generated by the direct entry of the light from the outside into the FD 53 is reduced. Hence, it is possible to exhibit more superior imaging performance

Further, in the pixel regions R110 in which the sensor pixel 110 is provided, the respective transistors, i.e., the TG 52, the RST 54, the FBEN 55, the OFG 56, the AMP 57, and the SEL 58 are disposed along the straight parts L51A to L51D configuring the substantially rectangular outer edge of the PD 51. Accordingly, the optical symmetry is excellent.

Further, in the sensor pixel 110, the OFG 56 and the AMP 57 share the drain D. Thus, it is possible to increase a ratio of the occupying area of the PD 51 to the area of the pixel region R110. Accordingly, it is advantageous in terms of miniaturization of the pixel array section 111 and the solid-state imaging device 101.

Further, in the sensor pixel 110, the first active region AR1 including the TG 52 and the second active region AR2 including the OFG 56 are disposed in the pixel region R110 in such a manner as to sandwich the PD 51 so as to secure high symmetry. Accordingly, it is possible to smoothly perform a transfer of the electric charge from the PD 51 to the TG 52 and a transfer of the electric charge from the PD 51 to the OFG 56.

Further, one or more well contacts 59 such as copper is coupled to the gap region GR of each sensor pixel 110 of the solid-state imaging device 101. Thus, it is possible to stabilize a potential of the semiconductor substrate 11 in each pixel region R110. Accordingly, it is possible to exhibit more superior imaging performance

<2. First Modification Example>

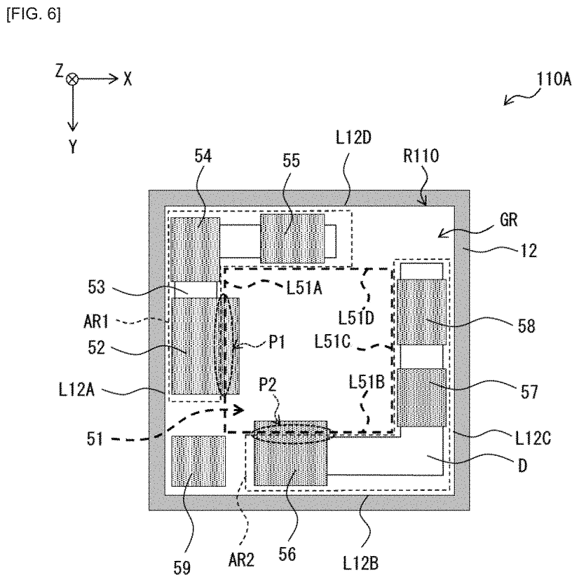

Next, referring to FIG. 6, a sensor pixel 110A according to a first modification example of the embodiment described above will be described. FIG. 6 is a schematic diagram illustrating an example of a plan configuration of the sensor pixel 110A, and corresponds to FIG. 3 that illustrates the sensor pixel 110 described in the embodiment described above. The sensor pixel 110A has substantially the same configuration as the sensor pixel 110 of FIG. 3, except that a layout of each component in the gap region GR of the pixel region R110 is different.

Specifically, in the sensor pixel 110A, the FD 53 is provided only between the straight part L51A and the straight part L12A of the gap region GR by providing the RST 54 at a corner part of the pixel region R110.

In this manner, in the sensor pixel 110A, it is provided only between the straight part L51A configuring the outer edge of the PD 51 and the straight part L12A configuring the outer edge of the pixel separation section 12. Thus, it is possible to reduce the occupying area in the X-Y plane of the FD 53 as compared with a case where the FD 53 is provided at a corner part of the pixel region R110 as with the sensor pixel 110 of the embodiment described above. Accordingly, a false signal generated by the direct entry of the light from the outside into the FD 53 is more reduced as compared with the sensor pixel 110 of the embodiment described above. Hence, it is possible to exhibit even more superior imaging performance

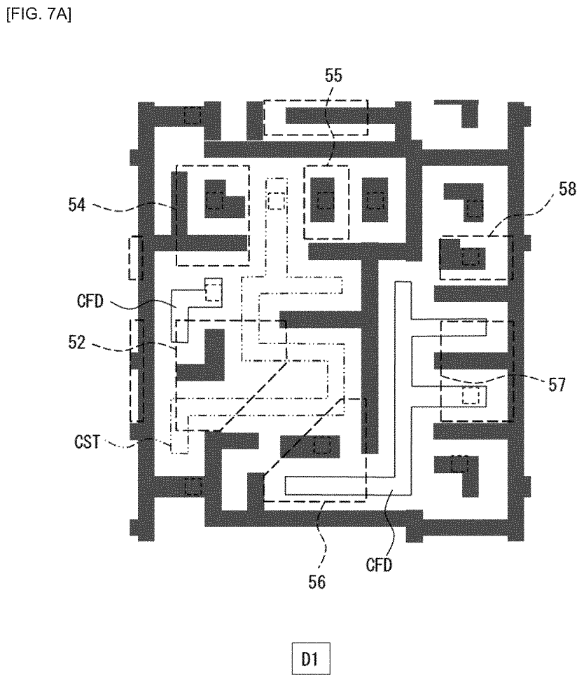

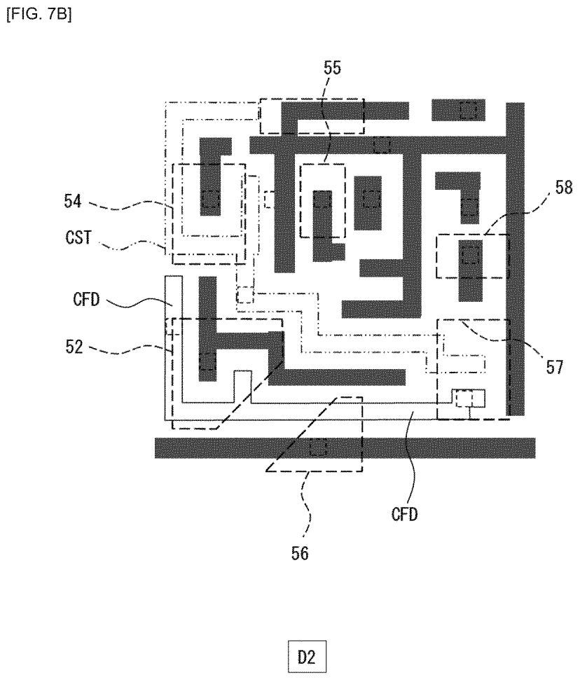

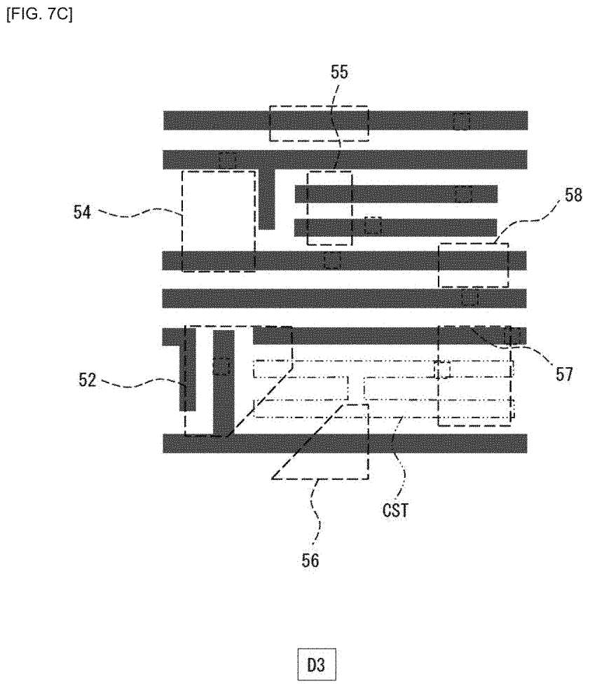

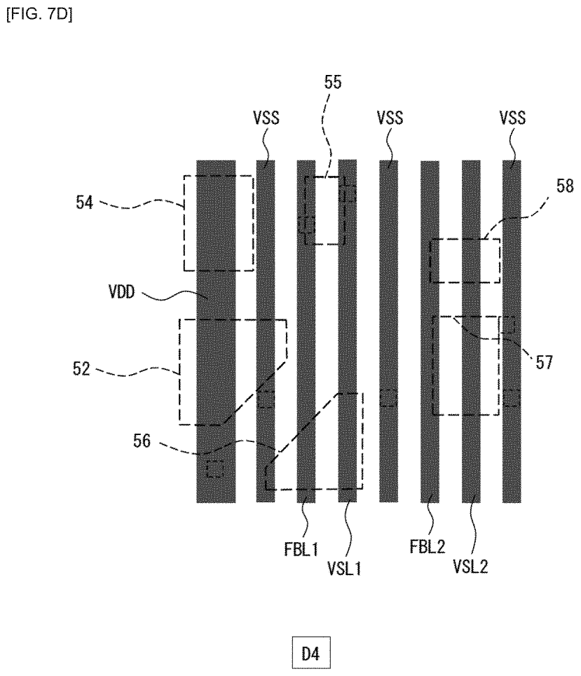

FIGS. 7A to 7D illustrate wiring line patterns of respective layers D1 to D4 extending in the X-Y plane of the sensor pixel 110A illustrated in FIG. 6. The layers D1 to D4 are stacked in order on the surface 11A of the semiconductor substrate 11.

A wiring line CFD whose contour is illustrated by a solid line in the layer D1 of FIG. 7A and the layer D2 of FIG. 7B forms the parasitic capacitance C__{F}D (see FIG. 2). In addition, a wiring line CST whose contour is illustrated by a two-dot chain line in the layers D1 to D3 of FIGS. 7A to 7C forms the parasitic capacitance C__{ST} (see FIG. 2). In the sensor pixel 110A, as illustrated in FIGS. 7A to 7C, the wiring line CFD and the wiring line CST each include two wiring line parts extending substantially side by side with respect to each other in a comb-like shape. Accordingly, it is possible to effectively secure the capacity necessary for the pixel circuit even when the pixel region R110 is minute.

Further, as illustrated in the layer D4 of FIG. 7D, two VSLs 117 and two FBLs extending in a Y-axis direction pass through the pixel region R110 of one sensor pixel 110. That is, it is possible to read out the image signal from one sensor pixel 110 by a first set of VSL 117 and FBL, and to read out the image signal from another sensor pixel 110 adjacent thereto in the column direction (the Y-axis direction) by a second set of VSL 117 and FBL. Accordingly, it is advantageous in terms of achieving a high frame rate.

<3. Second Modification Example>

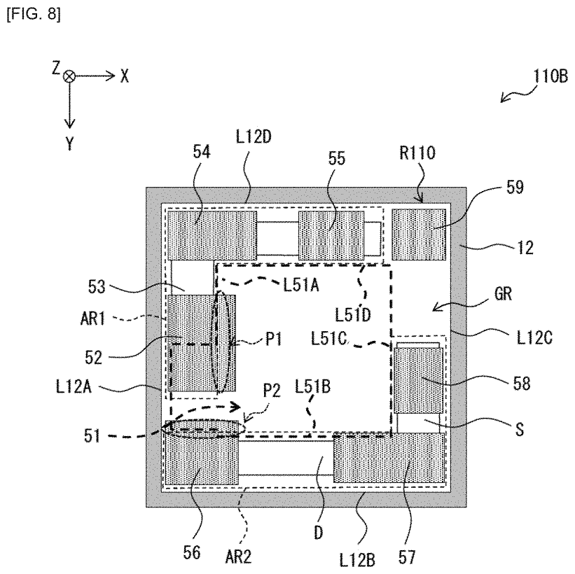

Next, referring to FIG. 8, a sensor pixel 110B according to a second modification example of the embodiment described above will be described. FIG. 8 is a schematic diagram illustrating an example of a plan configuration of the sensor pixel 110B, and corresponds to FIG. 6 that illustrates the sensor pixel 110A described in the first modification example described above. The sensor pixel 110B has substantially the same configuration as the sensor pixel 110A of FIG. 6, except that a layout of each component in the gap region GR of the pixel region R110 is different.

In the sensor pixel 110B, the OFG 56 and the AMP 57 of the second active region AR2 are also provided at corner parts of the pixel region R110 in addition to the RST 54 of the first active region AR1. The AMP 57 includes, for example, a drain D (a first diffusion region) extending in the X-axis direction and a source S (a second diffusion region) extending in the Y-axis direction. The AMP 57 share the drain D with the OFG 56.

As described above, in the sensor pixel 110B, some transistors are provided at the corner parts of the pixel region R110, and they are joined by the relatively simple planar shaped diffusion regions that extend linearly. Accordingly, it is advantageous in terms of a size reduction of the pixel region R110 as compared with the sensor pixels 110 and 110A of the embodiments described above. In addition, a degree of freedom in designing a layout of the pixel region R110 is improved, and it becomes easy to employ a plan configuration that is advantageous in increasing the occupying area ratio of the PD 51 in the pixel region R110, for example.

<4. Third Modification Example>

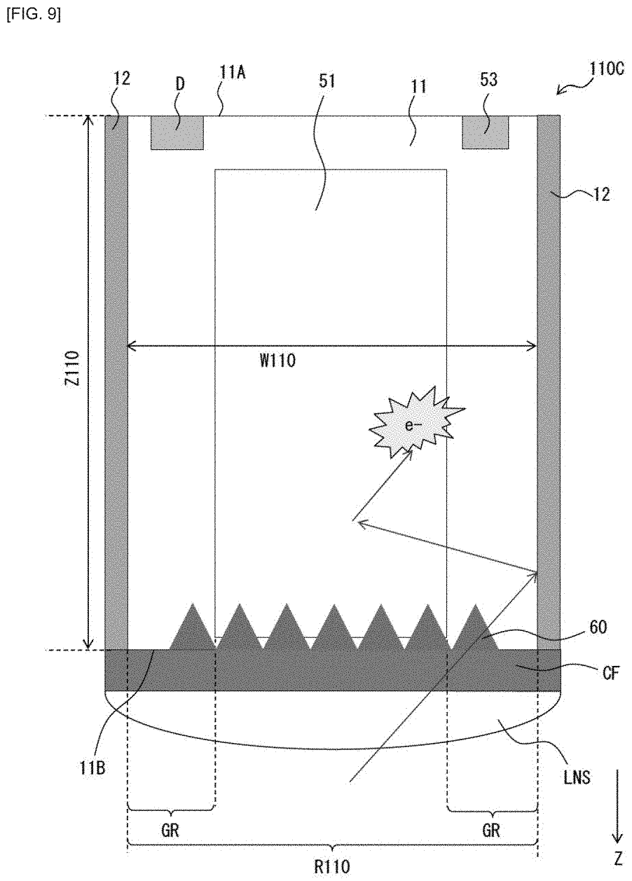

Next, referring to FIG. 9, a sensor pixel 110C according to a third modification example of the embodiment described above will be described. FIG. 9 is a schematic diagram illustrating an example of a cross-sectional configuration of the sensor pixel 110C, and corresponds to FIG. 4 that illustrates the sensor pixel 110 described in the embodiment described above. The sensor pixel 110C has substantially the same configuration as the sensor pixel 110A of FIG. 6, except that a scattering section 60 is provided in the vicinity of the back face 11B of the semiconductor substrate 11.

The scattering section 60 is a structure having a plurality of projections having a pointed shape and arranged along the back face 11B at a predetermined pitch, for example. The scattering section 60 is formed by selectively cutting the back face 11B of the semiconductor substrate 11. The scattering section 60 is adapted to guide the incident light that has entered the back face 11B to the PD 51 while moderately scattering the incident light.

As described above, in the sensor pixel 110C, the scattering section 60 is provided in the vicinity of the back face 11B of the semiconductor substrate 11. Thus, the incident light that enters the back face 11B from the outside through the on-chip lens LNS, the color filter CF, and the like is moderately scattered by the scattering section 60. Accordingly, an opportunity in which the incident light is reflected at an interface between the semiconductor substrate 11 and the pixel separation section 12 in the pixel region R110 increases and a light path length of the incident light becomes longer as compared with a case where no scattering section 60 is provided. As a result, it is possible to reduce the light amount of the incident light that directly enters the FD 53.

<5. Fourth Modification Example>

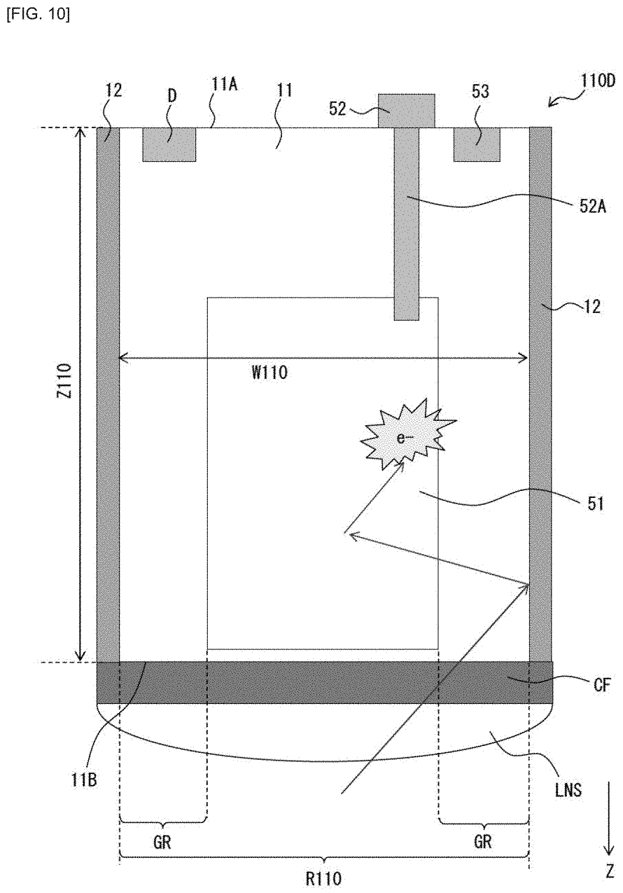

Next, referring to FIG. 10, a sensor pixel 110D according to a fourth modification example of the embodiment described above will be described. FIG. 10 is a schematic diagram illustrating an example of a cross-sectional configuration of the sensor pixel 110D, and corresponds to FIG. 4 that illustrates the sensor pixel 110 described in the embodiment described above. The sensor pixel 110D has substantially the same configuration as the sensor pixel 110 of FIG. 4, except that a vertical type trench gate 52G that joins the PD 51 and TG 52 is further provided. The vertical type trench gate 52G is provided so as to join the PD 51 and the TG 52, and serves as a path that transfers the electric charge from the PD 51 to the FD 53 that is a transfer destination. It should be noted that only one vertical type trench gate 52G may be disposed, or two or more vertical type trench gates 52G may be disposed.

As described above, in the sensor pixel 110D, the vertical type trench gate 52G extending in the thickness direction of the semiconductor substrate 11 is provided. Thus, it is possible to apply a biasing voltage to the semiconductor substrate 11. As a result, because it is possible to modulate a potential state of the semiconductor substrate 11, it is possible to smoothly transfer the electric charge from the PD 51 to the FD 53 via the TG 52. In addition, by providing the vertical type trench gate 52G, it is possible to increase the thickness Z110 of the semiconductor substrate 11 while maintaining the thickness (a size in the Z-axis direction) of the PD 51. For this reason, it is possible to increase a distance from the back face 11B on which the incident light is incident to the FD 53 provided in the vicinity of the surface 11A. Accordingly, a light path length of the incident light entering from the back face 11B and propagating in the pixel region R110 becomes long, and it is possible to reduce the light amount of the incident light that directly reaches the FD 53 consequently.

<6. Fifth Modification Example>

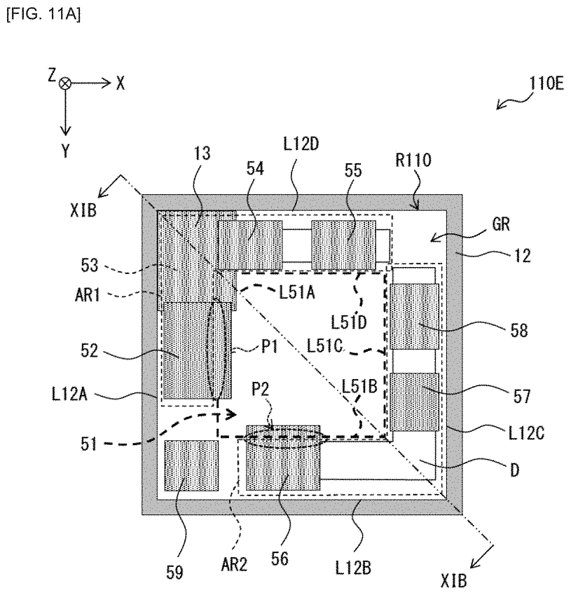

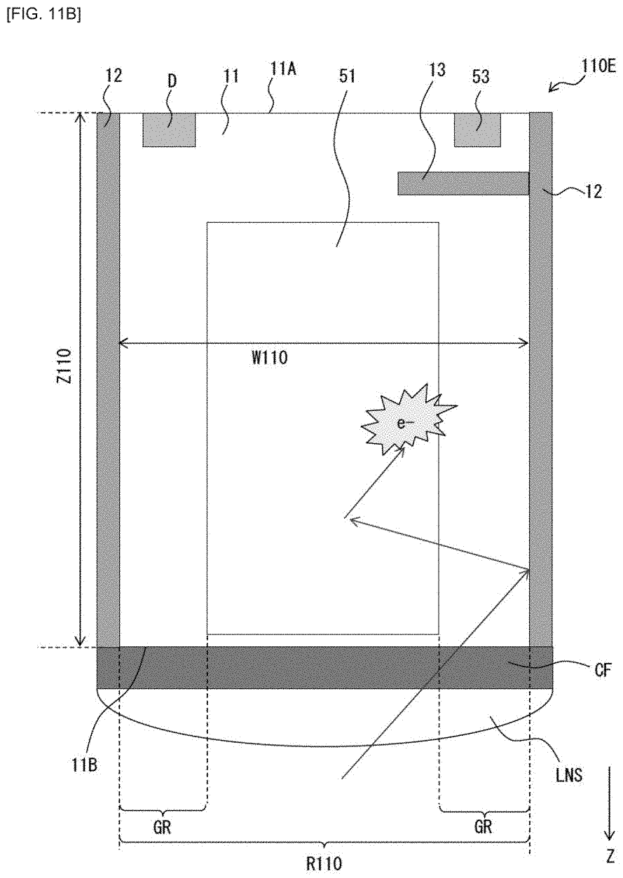

Next, referring to FIGS. 11A and 11B, a sensor pixel 110E according to a fifth modification example of the embodiment described above will be described. FIG. 11A is a schematic diagram illustrating an example of a plan configuration of the sensor pixel 110E, and corresponds to FIG. 3 that illustrates the sensor pixel 110 described in the embodiment described above. FIG. 11B is a schematic diagram illustrating an example of a cross-sectional configuration of the sensor pixel 110E, and corresponds to FIG. 4 that illustrates the sensor pixel 110 described in the embodiment described above. The sensor pixel 110E has substantially the same configuration as the sensor pixel 110 illustrated in FIGS. 3 and 4, except that a horizontal light-blocking film 13 is further provided.

As illustrated in FIGS. 11A and 11B, the horizontal light-blocking film 13 is disposed at a corner part where the straight part L12A and the straight part L12D intersect, for example, and is provided so as to overlap with the FD 53 in the thickness direction (the Z-axis direction). The horizontal light-blocking film 13 is formed to extend in the X-Y plane between the back face 11B on which the incident light is incident and the FD 53, e.g., between the PD 51 and the FD 53 in the thickness direction (the Z-axis direction).

The horizontal light-blocking film 13 is a member that hinders the entry of the light into the FD 53, and reduces the generation of the false signal resulting from the entry into the FD 53 of the light that has transmitted through the PD 51. The horizontal light-blocking film 13 includes, for example, the same material as the pixel separation section 12. It should be note that the light that has entered from the back face 11B and has transmitted through the PD 51 without being absorbed by the PD 51 is reflected by the horizontal light-blocking film 13 and eventually enters the PD 51 again. That is, the horizontal light-blocking film 13 is a reflector as well, and causes the light that has transmitted through the PD 51 to enter the PD 51 again to thereby increase a photoelectric conversion efficiency.

Further, the horizontal light-blocking film 13 may also be coupled to the pixel separation section 12. In this case, the pixel separation section 12 and the horizontal light-blocking film 13 each have a two-layer structure of, for example, an inner layer part and an outer layer part that surrounds the periphery thereof. The inner layer part includes, for example, a material containing at least one of a simple metal, a metal alloy, a metal nitride, or a metal silicide having a light-shielding property. More specifically, examples of a constituent material of the inner layer part include Al (aluminum), Cu (copper), Co (cobalt), W (tungsten), Ti (titanium), Ta (tantalum), Ni (nickel), Mo (molybdenum), Cr (chromium), Ir (iridium), platinum iridium, TiN (titanium nitride), and a tungsten silicon compound. Among them, Al (aluminum) is the most optically preferable constituent material. It should be noted that the inner layer part may include graphite or an organic material. The outer layer part includes an insulating material such as, for example, SiOx (silicon oxide). The outer layer part secures an electrically insulating property between the inner layer part and the semiconductor substrate 11.

It should be noted that it is possible to form the light-blocking film 14 extending in the X-Y plane by forming a space inside the semiconductor substrate 11 by, for example, wet etching, and filling the space with the material described above thereafter. In the wet etching process, for example, in a case where the semiconductor substrate 11 includes Si (111), a predetermined alkaline aqueous solution is used to perform crystalline anisotropic etching that utilizes a property in which an etching rate differs depending on a plane orientation of the Si (111). More specifically, for the Si (111) substrate, a property is utilized in which the etching rate in a <110> direction becomes sufficiently high with respect to the etching rate in a <111> direction. As a predetermined aqueous alkaline solution, KOH, NaOH, CsOH or the like is applicable if the aqueous alkaline solution is an inorganic solution, and EDP (ethylenediamine pyrocatechol aqueous solution), N₂H₄ (hydrazine), NH₄OH (ammonium hydroxide), TMAH (tetramethylammonium hydroxide) or the like is applicable if the aqueous alkaline solution is an organic solution.

As described above, in the sensor pixel 110E, the horizontal light-blocking film 13 is further provided between the back face 11B and the FD 53. Accordingly, the false signal generated by the direct entry of the light from the outside into the FD 53 is even more reduced. Hence, it is possible to exhibit even more superior imaging performance.

<7. Example of Application to Electronic Apparatus >

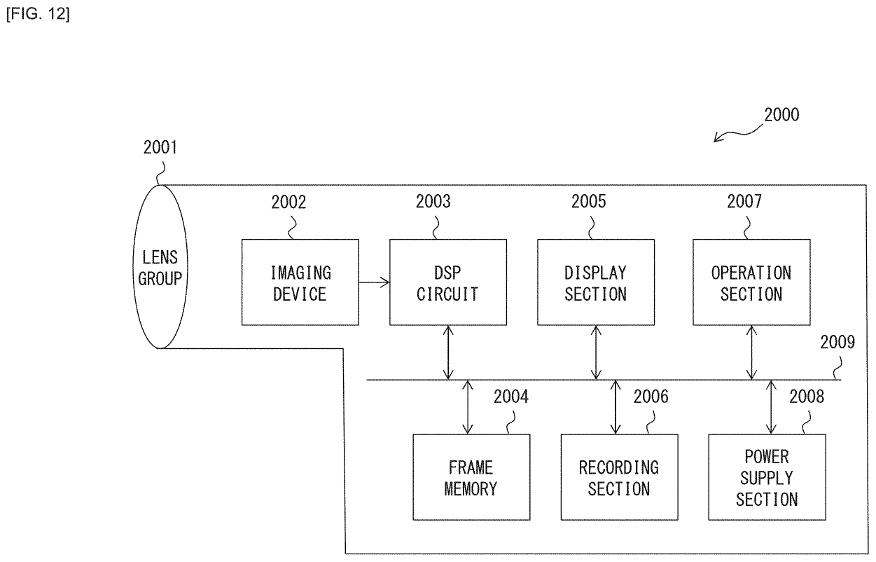

FIG. 12 is a block diagram illustrating a configuration example of a camera 2000 as an electronic apparatus to which the present technology is applied.

The camera 2000 includes an optical section 2001 configured by a lens group and the like, an imaging device (an image pickup device) 2002 to which the solid-state imaging device 101 described above or the like is applied (hereinafter, referred to as the solid-state imaging device 101 or the like), and a DSP (Digital Signal Processor) circuit 2003 as a camera signal process circuit. In addition, the camera 2000 also includes a frame memory 2004, a display section 2005, a recording section 2006, an operation section 2007, and a power supply section 2008. The DSP circuit 2003, the frame memory 2004, the display section 2005, the recording section 2006, the operation section 2007, and the power supply section 2008 are coupled mutually via a bus line 2009.

The optical section 2001 takes in the incident light (image light) from the subject and forms an image on an imaging surface of the imaging device 2002. The imaging device 2002 converts a light amount of the incident light having been subjected to the image formation on the imaging surface by the optical section 2001 into an electric signal on a pixel basis and outputs the electric signal as a pixel signal.

The display section 2005 is configured by, for example, a panel-type display device such as a liquid crystal panel or an organic EL panel, and displays a moving image or a still image captured by the imaging device 2002. The recording section 2006 records the moving image or the still image captured by the imaging device 2002 on a recording medium such as a hard disk or a semiconductor memory.

The operation section 2007 issues an operation command for various functions of the camera 2000 on the basis of an operation performed by a user. The power supply section 2008 provides, as appropriate, various power supplies serving as operation power supplies of the DSP circuit 2003, the frame memory 2004, the display section 2005, the recording section 2006, and the operation section 2007 to these supply targets.

As described above, it is possible to expect a favorable image to be obtained by using the solid-state imaging device 101A or the like described above as the imaging device 2002.

<8. Example of Application to Mobile Body>

It is possible to apply a technique according to the present disclosure (the present technology) to a variety of products. For example, the technique according to the present disclosure may be implemented as a device to be mounted on any type of mobile body of any type, such as a vehicle, an electric vehicle, a hybrid electric vehicle, a motorcycle, a bicycle, personal mobility, an airplane, a drone, a vessel, a robot, or the like.

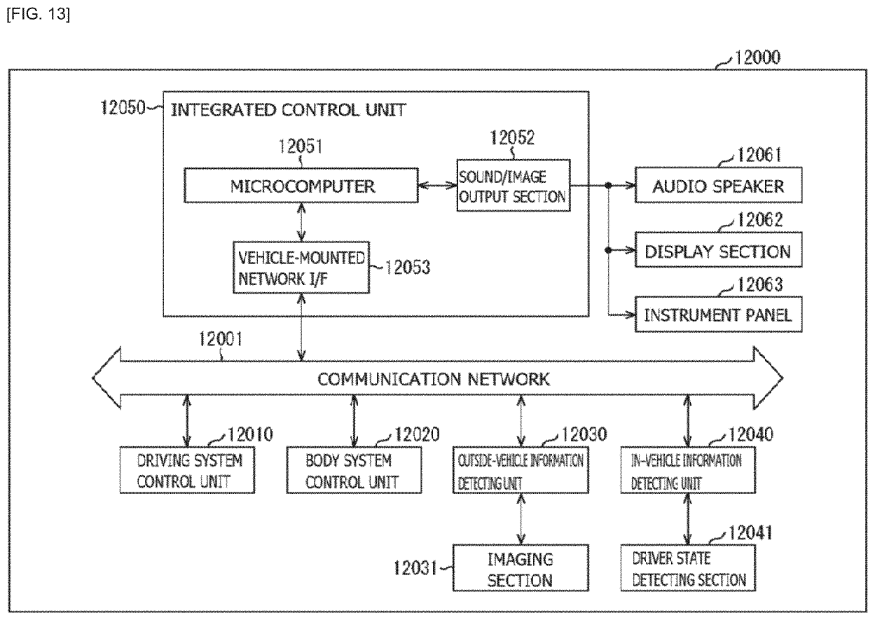

FIG. 13 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 13, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (UF) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 13, an audio speaker 12061, a display section 12062, and an instrument panel 12063 are illustrated as the output device. The display section 12062 may, for example, include at least one of an on-board display and a head-up display.

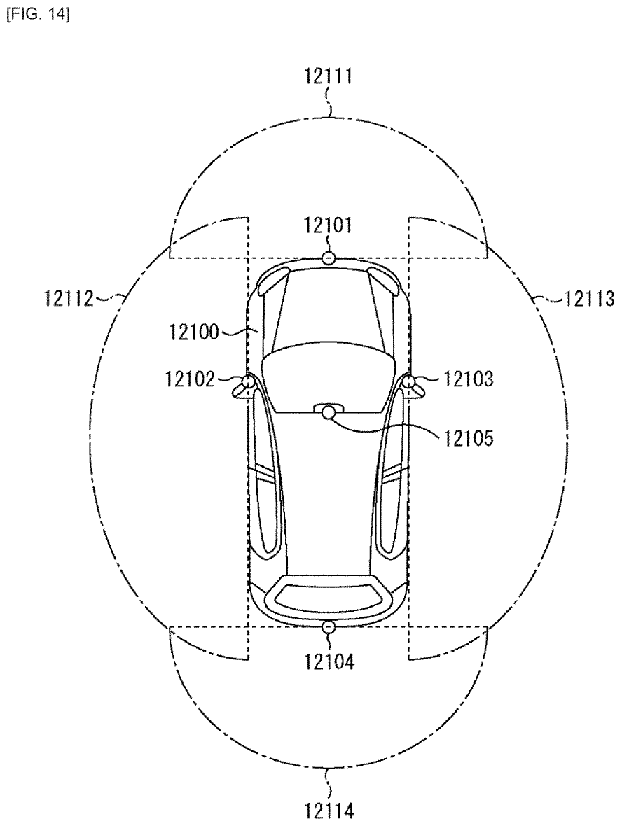

FIG. 14 is a diagram depicting an example of the installation position of the imaging section 12031.

In FIG. 14, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 14 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which a technique according to the present disclosure may be applied has been described above. A technique according to the present disclosure may be applied to the imaging section 12031 among the configurations described above. Specifically, it is possible to apply the solid-state imaging device 101 or the like illustrated in FIG. 1 and the like to the imaging section 12031. By applying a technique according to the present disclosure to the imaging section 12031, it is possible to expect an excellent operation of the vehicle control system.

<9. Other Modification Examples>

Although the present disclosure has been described with reference to some embodiments and the modification examples, the present disclosure is not limited to the embodiments and the like described above, and various modifications can be made. For example, the present disclosure is not limited to the backside illumination image sensor, and is applicable to a front-side illumination image sensor as well.

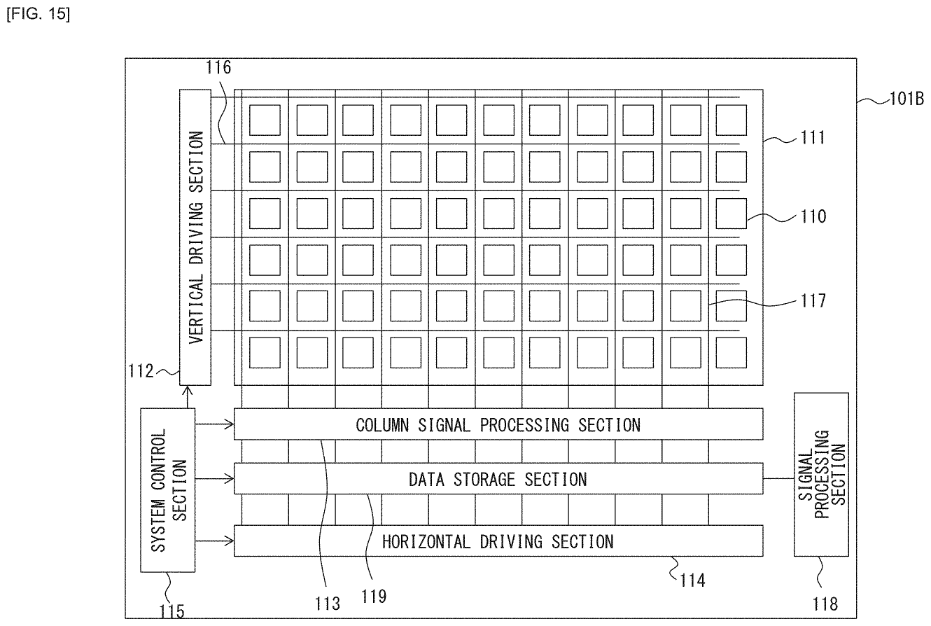

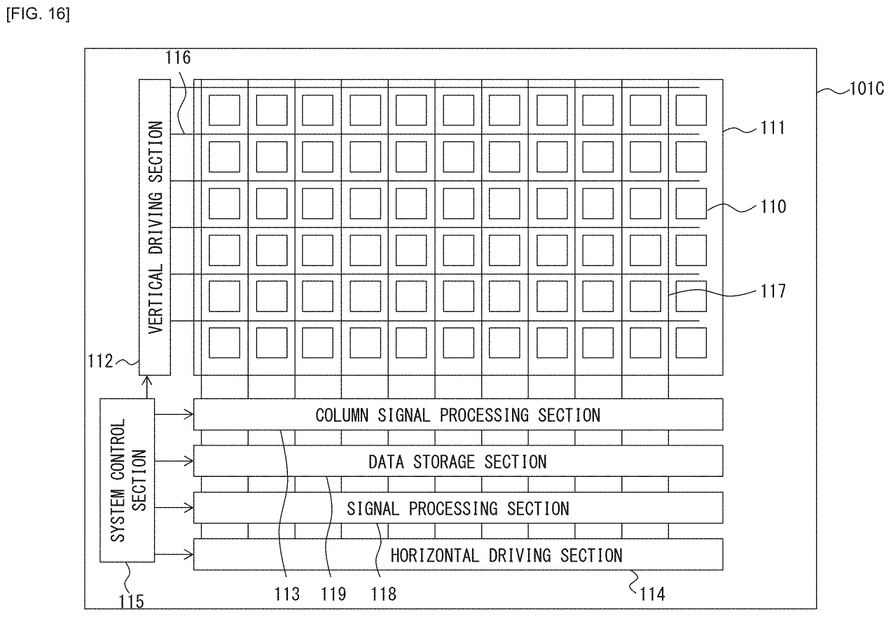

It is to be noted that the solid-state imaging device of the present technology is not limited to the solid-state imaging device 101 illustrated in FIG. 1, and may have a configuration such as a solid-state imaging device 101A illustrated in FIG. 15 or a solid-state imaging device 101B illustrated in FIG. 16, for example. FIG. 15 is a block diagram illustrating a configuration example of the solid-state imaging device 101A according to a first modification example of the solid-state imaging device of the present technology. FIG. 16 is a block diagram illustrating a configuration example of a solid-state imaging device 101B according to a second modification example of the solid-state imaging device of the present technology.

In the solid-state imaging device 101A of FIG. 15, the data storage section 119 is disposed between the column signal processing section 113 and the horizontal driving section 114, and a pixel signal outputted from the column signal processing section 113 is supplied to the signal processing section 118 via the data storage section 119.

Further, in the solid-state imaging device 101B of FIG. 16, the data storage section 119 and the signal processing section 118 are disposed in parallel between the column signal processing section 113 and the horizontal driving section 114. In the solid-state imaging device 101B, the column signal processing section 113 performs an A/D conversion that converts an analog pixel signal into a digital pixel signal, for each column of the pixel array section 111 or for each of multiple columns of the pixel array section 111.

Further, the imaging device of the present disclosure is not limited to an imaging device that detects a light amount distribution of the visible light and captures the visible light as an image, and may be an imaging device that captures a distribution of incident amount of infrared rays, X-rays, particles, or the like as an image.

Further, the imaging device of the present disclosure may also be in the form of a module in which the imaging section and the signal processing section or the optical system are packaged together.

According to the imaging device and the electronic apparatus as one embodiment of the present disclosure, the semiconductor layer is separated into the plurality of pixel regions in in-plane direction by providing the pixel separation section that extends from the surface to the back face of the semiconductor layer. Thus, the color mixture reduction effect between the adjacent pixels is obtained. Further, the electric charge voltage conversion section is provided in the gap region. Thus, the false signal generated by the direct entry of the light from the outside into the electric charge voltage conversion section is reduced. Hence, it is possible to exhibit more superior imaging performance.

It is to be noted that the effects described in the present specification are mere examples and description thereof is non-limiting. Other effects may be also provided. Further, the present technology may have the following configurations.
(1)

An imaging device including:

a semiconductor layer having a surface that extends in an in-plane direction, and a back face positioned on an opposite side of the surface in a thickness direction that is orthogonal to the in-plane direction;

a pixel separation section that extends from the surface to the back face in the thickness direction, and separates the semiconductor layer into a plurality of pixel regions in the in-plane direction;

a plurality of photoelectric conversion sections respectively provided in the plurality of pixel regions of the semiconductor layer separated by the pixel separation section, and each configured to generate, by a photoelectric conversion, electric charge corresponding to a light amount of incident light from the back face; and

a plurality of electric charge voltage conversion sections respectively provided in a plurality of gap regions, the plurality of gap regions being disposed in the in-plane direction between the plurality of photoelectric conversion sections and the pixel separation section out of the plurality of pixel regions, the plurality of electric charge voltage conversion sections respectively accumulating the electric charges generated by the respective plurality of photoelectric conversion sections, and respectively converting the accumulated electric charges into electric signals and outputting the converted electric signals.
(2)

The imaging device according to (1), further including:

a first active region including a transfer transistor that is coupled to the photoelectric conversion section at a first connection point, and transfers the electric charge from the photoelectric conversion section to the electric charge voltage conversion section; and

a second active region including a discharge transistor that is coupled to the photoelectric conversion section at a second connection point different from the first connection point, and discharges the electric charge from the photoelectric conversion section to outside to deplete the photoelectric conversion section.
(3)

The imaging device according to (2), in which

the pixel region has a rectangular first outer edge that includes a first straight part in the in-plane direction,

the photoelectric conversion section has a rectangular second outer edge that includes a second straight part in the in-plane direction, the second straight part facing the first straight part, and

the electric charge voltage conversion section is provided between the first straight part and the second straight part in the in-plane direction.
(4)

The imaging device according to (2) or (3), in which

the second active region further includes an amplification transistor in the in-plane direction, and

the amplification transistor is provided at a corner part of the pixel region, and includes a first diffusion region extending in a first direction in the in-plane direction, and a second diffusion region extending in a second direction that is orthogonal to the first direction in the in-plane direction.
(5)

The imaging device according to (4), in which the discharge transistor shares the first diffusion region with the amplification transistor.
(6)

The imaging device according to any one of (1) to (5), in which the electric charge voltage conversion section is provided between the surface and the photoelectric conversion section in the thickness direction.
(7)

The imaging device according to any one of (1) to (6), further including a light-blocking film that is provided between the photoelectric conversion section and the electric charge voltage conversion section in the thickness direction, and extends in the in-plane direction.
(8)

The imaging device according to any one of (1) to (7), further including a scattering section that is provided on the back face of the semiconductor layer or between the back face and the photoelectric conversion section, and scatters the incident light that enters the back face.
(9)

The imaging device according to any one of (1) to (8), further including a transfer transistor that includes a trench gate, the trench gate extending from the surface of the semiconductor layer toward the back face to the photoelectric conversion section, the transfer transistor transferring the electric charge from the photoelectric conversion section to the electric charge voltage conversion section via the trench gate.
(10)

The imaging device according to any one of (1) to (9), in which the incident light includes infrared light.
(11)

The imaging device according to any one of (1) to (10), further including a well contact coupled to each of the plurality of gap regions.
(12)

An electronic apparatus with an imaging device, the imaging device including:

a semiconductor layer having a surface that extends in an in-plane direction, and a back face positioned on an opposite side of the surface in a thickness direction that is orthogonal to the in-plane direction;

a pixel separation section that extends from the surface to the back face in the thickness direction, and separates the semiconductor layer into a plurality of pixel regions in the in-plane direction;

a plurality of photoelectric conversion sections respectively provided in the plurality of pixel regions of the semiconductor layer separated by the pixel separation section, and each configured to generate, by a photoelectric conversion, electric charge corresponding to a light amount of incident light from the back face; and

a plurality of electric charge voltage conversion sections respectively provided in a plurality of gap regions, the plurality of gap regions being disposed in the in-plane direction between the plurality of photoelectric conversion sections and the pixel separation section out of the plurality of pixel regions, the plurality of electric charge voltage conversion sections respectively accumulating the electric charges generated by the respective plurality of photoelectric conversion sections, and respectively converting the accumulated electric charges into electric signals and outputting the converted electric signals.

The present application claims the benefit of Japanese Priority Patent Application JP2019-100342 filed with the Japan Patent Office on May 29, 2019, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. An imaging device comprising:
a semiconductor layer having a surface that extends in an in-plane direction, and a back face positioned on an opposite side of the surface in a thickness direction that is orthogonal to the in-plane direction;
a pixel separation section that extends from the surface to the back face in the thickness direction, and separates the semiconductor layer into a plurality of pixel regions in the in-plane direction;
a plurality of photoelectric conversion sections respectively provided in the plurality of pixel regions of the semiconductor layer separated by the pixel separation section, and each configured to generate, by a photoelectric conversion, electric charge corresponding to a light amount of incident light from the back face; and
a plurality of electric charge voltage conversion sections respectively provided in a plurality of gap regions, the plurality of gap regions being disposed in the in-plane direction between the plurality of photoelectric conversion sections and the pixel separation section out of the plurality of pixel regions, the plurality of electric charge voltage conversion sections respectively accumulating the electric charges generated by the respective plurality of photoelectric conversion sections, and respectively converting the accumulated electric charges into electric signals and outputting the converted electric signals.

2. The imaging device according to claim 1, further comprising:
a first active region including a transfer transistor that is coupled to the photoelectric conversion section at a first connection point, and transfers the electric charge from the photoelectric conversion section to the electric charge voltage conversion section; and
a second active region including a discharge transistor that is coupled to the photoelectric conversion section at a second connection point different from the first connection point, and discharges the electric charge from the photoelectric conversion section to outside to deplete the photoelectric conversion section.

3. The imaging device according to claim 2, wherein
the pixel region has a rectangular first outer edge that includes a first straight part in the in-plane direction,
the photoelectric conversion section has a rectangular second outer edge that includes a second straight part in the in-plane direction, the second straight part facing the first straight part, and
the electric charge voltage conversion section is provided between the first straight part and the second straight part in the in-plane direction.

4. The imaging device according to claim 2, wherein
the second active region further includes an amplification transistor in the in-plane direction, and
the amplification transistor is provided at a corner part of the pixel region, and includes a first diffusion region extending in a first direction in the in-plane direction, and a second diffusion region extending in a second direction that is orthogonal to the first direction in the in-plane direction.

5. The imaging device according to claim 4, wherein the discharge transistor shares the first diffusion region with the amplification transistor.

6. The imaging device according to claim 1, wherein the electric charge voltage conversion section is provided between the surface and the photoelectric conversion section in the thickness direction.

7. The imaging device according to claim 1, further comprising a light-blocking film that is provided between the photoelectric conversion section and the electric charge voltage conversion section in the thickness direction, and extends in the in-plane direction.

8. The imaging device according to claim 1, further comprising a scattering section that is provided on the back face of the semiconductor layer or between the back face and the photoelectric conversion section, and scatters the incident light that enters the back face.

9. The imaging device according to claim 1, further comprising a transfer transistor that includes a trench gate, the trench gate extending from the surface of the semiconductor layer toward the back face to the photoelectric conversion section, the transfer transistor transferring the electric charge from the photoelectric conversion section to the electric charge voltage conversion section via the trench gate.

10. The imaging device according to claim 1, wherein the incident light comprises infrared light.

11. The imaging device according to claim 1, further comprising a well contact coupled to each of the plurality of gap regions.

12. An electronic apparatus with an imaging device, the imaging device comprising:
a semiconductor layer having a surface that extends in an in-plane direction, and a back face positioned on an opposite side of the surface in a thickness direction that is orthogonal to the in-plane direction;
a pixel separation section that extends from the surface to the back face in the thickness direction, and separates the semiconductor layer into a plurality of pixel regions in the in-plane direction;
a plurality of photoelectric conversion sections respectively provided in the plurality of pixel regions of the semiconductor layer separated by the pixel separation section, and each configured to generate, by a photoelectric conversion, electric charge corresponding to a light amount of incident light from the back face; and
a plurality of electric charge voltage conversion sections respectively provided in a plurality of gap regions, the plurality of gap regions being disposed in the in-plane direction between the plurality of photoelectric conversion sections and the pixel separation section out of the plurality of pixel regions, the plurality of electric charge voltage conversion sections respectively accumulating the electric charges generated by the respective plurality of photoelectric conversion sections, and respectively converting the accumulated electric charges into electric signals and outputting the converted electric signals.
